(19) United States
(12) Patent Application Publication
(10) Pub. No.: US 2025/0287748 A1
(43) Pub. Date: Sep. 11, 2025

(54) LIGHT-EMITTING DIODE WITH HIGH REVERSE VOLTAGE TOLERANCE, LIGHT SOURCE BOARD INCLUDING THE SAME, AND LIGHTING DEVICE INCLUDING THE SAME

(71) Applicant: Xiamen PVTECH Co., Ltd., Xiamen (CN)

(72) Inventors: ZHIRONG LIN, Xiamen (CN); Bohao Zhang, Xiamen (CN); Fuxing Lu, Xiamen (CN); Jinping Chen, Xiamen (CN)

(73) Assignee: Xiamen PVTECH Co., Ltd., Xiamen (CN)

(21) Appl. No.: 19/074,476

(22) Filed: Mar. 10, 2025

(30) Foreign Application Priority Data
Mar. 8, 2024 (CN) 202410265284.0
Mar. 12, 2024 (CN) 202410282271.4
Apr. 30, 2024 (CN) 202410544764.0

(51) Int. Cl. H10H 20/857; H10H 20/858

(52) U.S. Cl. CPC H10H 20/857; H10H 20/8582

(57) ABSTRACT

A light-emitting diode with high reverse voltage tolerance includes a holder, a positive pad, a negative pad and a light source. The positive pad is disposed in the holder, and includes a first main body and a first extension portion connected to each other. The negative pad is disposed in the holder, and includes a second main body and two second extension portions connected to the second main body. The light source is disposed in the holder and electrically connected to the positive pad and the negative pad. The second extension portions extend toward the positive pad to form an accommodating space between the second extension portions, and the first extension portion extends toward the accommodating space.

### BACKGROUND OF THE INVENTION

### 1. Field of the Invention

The present invention relates to a light-emitting diode, in particular to a light-emitting diode with high reverse voltage tolerance. The present invention further relates to the light source board including the light-emitting diode, and the lighting device including the light-emitting diode.

### 2. Description of the Prior Art

Most currently available lighting devices use metal housings to improve heat dissipation, and these metal housings are connected to a grounding point to comply with safety regulations. However, a parasitic capacitance is formed between the copper foil of the light source board and the metal housing. When the switch is turned on, an AC voltage is applied to the light sources on the light source board (which are connected to the copper foil). Since the parasitic capacitance conducts when an AC voltage is applied, the light sources on the light source board are subjected to a certain reverse voltage. If this reverse voltage is applied to the light sources for a long time, it to the light sources may be damaged due to this reverse voltage.

To solve the above problems, several solutions have been proposed. One commonly used solution is to add a Zener diode to the circuit of the lighting device. However, this solution increases costs and reduces luminous efficiency.

Another commonly used solution is to add an isolated power supply to the circuit of the lighting device. However, this solution also increases costs and reduces power efficiency.

Yet another commonly used solution is to add a resistor (or capacitor) to the circuit of the lighting device and connect the resistor in parallel with the light sources. However, this solution also increases costs and reduces luminous efficiency.

### SUMMARY OF THE INVENTION

One embodiment of the present invention provides a light-emitting diode with high reverse voltage tolerance, which includes a holder, a positive pad, a negative pad and a light source. The positive pad is disposed in the holder, and includes a first main body and a first extension portion connected to each other. The negative pad is disposed in the holder, and includes a second main body and two second extension portions connected to the second main body. The light source is disposed in the holder and electrically connected to the positive pad and the negative pad. The second extension portions extend toward the positive pad to form an accommodating space between the second extension portions, and the first extension portion extends toward the accommodating space.

In one embodiment, a part of the first extension portion is disposed in the accommodating space.

In one embodiment, the first extension portion is disposed between the two second extension portions, and there is a gap between the first extension portion and any one of the second extension portions.

In one embodiment, the cross-section of the negative pad is U-shaped.

In one embodiment, the light-emitting diode further includes a reflector cup disposed within the holder. The light source is disposed in the reflector cup, and the reflector cup is filled with a filling material.

Another embodiment of the present invention provides a light-emitting diode with high reverse voltage tolerance, which includes a holder, a positive pad, a negative pad and a light source. The positive pad is disposed in the holder, and includes a first main body and a plurality of first extension portions connected to each other. The negative pad disposed in the holder, and includes a second main body and a plurality of second extension portions connected to the second main body. The light source is disposed in the holder and electrically connected to the positive pad and the negative pad. The second extension portions extend toward the positive pad to form a plurality of accommodating spaces between the second extension portions corresponding to the first extension portions respectively. Each of the first extension portions extends toward the accommodating space corresponding thereto.

In one embodiment, a part of each first extension portion is disposed in the accommodating space corresponding thereto.

In one embodiment, each of the first extension portions is disposed between two the second extension portions adjacent with each other, and there is a gap between the first extension portion and the second extension portions adjacent with each other.

In one embodiment, the number of the second extension portions is greater than the number of the first extension portions.

In one embodiment, the light-emitting diode further includes a reflector cup disposed in the holder. The light source is disposed in the reflector cup, and the reflector cup is filled with a filling material.

Yet another embodiment of the present invention provides a light source board, which includes a circuit board, a first copper foil, a plurality of second copper foil and a plurality of light-emitting diodes. The first copper foil is disposed on the circuit board. The second copper foils are disposed on the circuit board, and each of the second copper foils has a branch structure. The light-emitting diodes are disposed on the circuit board, and electrically connected to the first copper foil and the second copper foils. The branch structures of each of the second copper foils are interleaved with the branch structure of the second copper foil adjacent thereto.

In one embodiment, each of the light-emitting diodes is as described in either of the previous embodiments.

Still another embodiment of the present invention provides a lighting device, which includes a current-limiting diode, a plurality of light-emitting diodes, a rectifier, and a power input terminal. The light-emitting diodes are connected in series to form a series circuit, and the series circuit is connected in parallel with the current-limiting diode. Each of the light-emitting diodes has a parasitic capacitor. The rectifier is connected to the light-emitting diodes, and the power input terminal is connected to an external power source and the rectifier. The current-limiting diode forms a discharge path, and the discharge current generated by the parasitic capacitor of each of the light-emitting diodes is released via the discharge path.

In one embodiment, each of the light-emitting diodes is as described in either of the previous embodiments.

Further scope of applicability of the present application will become more apparent from the detailed description given hereinafter. However, it should be understood that the detailed description and specific examples, while indicating exemplary embodiments of the present invention, are given by way of illustration only, since various changes and modifications within the spirit and scope of the present invention will become apparent to those skilled in the art from this detailed description.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 is a cross-sectional view of a structure of a light-emitting diode with high reverse voltage tolerance in accordance with a first embodiment of the present invention.

FIG. 2 is a cross-sectional view of a light-emitting diode with high reverse voltage tolerance in accordance with a second embodiment of the present invention.

FIG. 3 is a flowchart of a manufacturing method of a light-emitting diode with high reverse voltage tolerance in accordance with a third embodiment of the present invention.

FIG. 4 is a top view of a structure of a light source board with a branch layout structure in accordance with a fourth embodiment of the present invention.

FIG. 5 is a top view of a structure of a light source board with a branch layout structure in accordance with a fifth embodiment of the present invention.

FIG. 6 is a flowchart of a manufacturing method of a light source board in accordance with a sixth embodiment of the present invention.

FIG. 7 is a circuit diagram of a lighting device with a reverse voltage clamp release mechanism in accordance with a seventh embodiment of the present invention.

FIG. 8 is a schematic view of an operating state of the lighting device with the reverse voltage clamp release mechanism in accordance with the seventh embodiment of the present invention.

FIG. 9 is a circuit diagram of a lighting device with a reverse voltage clamp release mechanism in accordance with an eighth embodiment of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing. It should be understood that, when it is described that an element is “coupled” or “connected” to another element, the element may be “directly coupled” or “directly connected” to the other element or “coupled” or “connected” to the other element through a third element. In contrast, it should be understood that, when it is described that an element is “directly coupled” or “directly connected” to another element, there are no intervening elements.

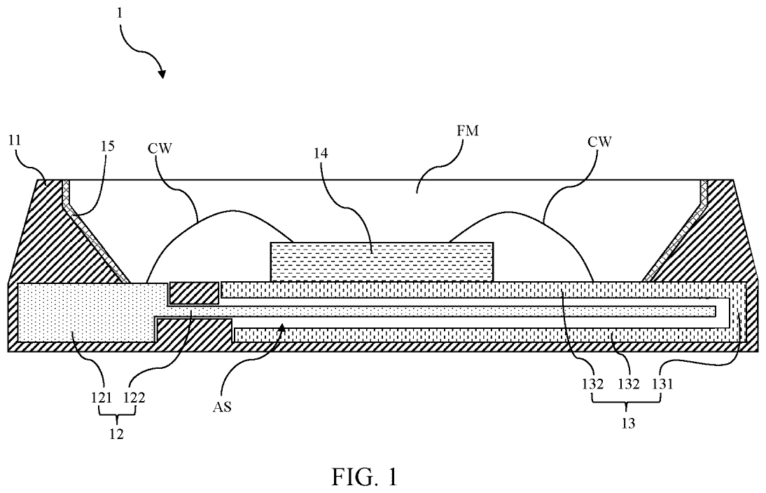

Please refer to FIG. 1, which is a cross-sectional view of a structure of a light-emitting diode with high reverse voltage tolerance in accordance with a first embodiment of the present invention. As shown in FIG. 1, the light-emitting diode 1 includes a holder 11, a positive pad 12, a negative pad 13, a light source 14, and a reflector cup 15.

The positive pad 12 is disposed in the holder 11. The positive pad 12 includes a first main body 121 and a first extension portion 122 connected to each other. In one embodiment, the positive pad 12 may be made of copper, aluminum, iron, or other metal materials.

The negative pad 13 is disposed in the holder 11. The negative pad 13 includes a second main body 131 and two second extension portions 132. The two second extension portions 132 are connected to the second main body 131, forming a U-shaped cross-section for the negative pad 13. In one embodiment, the negative pad 13 may be made of copper, aluminum, iron, or other metal materials.

The reflector cup 15 is disposed in the holder 11. In one embodiment, the reflector cup 15 may be made of metal, plastic, or other similar materials.

The light source 14 is disposed in the holder 11 and inside the reflector cup 15. The reflector cup 15 is filled with a filling material FM (such as a mixture of phosphor and adhesive). The light source 14 is electrically connected to the positive pad 12 and the negative pad 13 via a wire CW. The light source 14 may be an LED die.

As shown in FIG. 1, the two second extension portions 132 of the negative pad 13 extend toward the positive pad 12, such that an accommodating space AS is formed between the second extension portions 132. The first extension portion 122 extends toward the accommodating space AS. This structural design allows the positive pad 12 and the negative pad 13 to complement each other, forming a complementary pad structure. Thus, the first extension portion 122 is disposed between the two second extension portions 132, and there is a gap between the first extension portion 122 and each second extension portion 132. In this embodiment, a part of the first extension portion 122 is disposed in the accommodating space AS, while another portion is exposed outside the accommodating space AS. In another embodiment, the first extension portion 122 may be entirely disposed in the accommodating space AS.

A capacitor (distributed capacitance) can be formed between the first extension portion 122 and any adjacent second extension portion 132, and this capacitor is connected in parallel with the parasitic capacitance of the light source 14 itself. As a result, the above structure is equal to the light source 14 connected in parallel with multiple capacitors, which increases the overall distributed capacitance of the light source 14. When a reverse voltage is applied to the light source 14, the distributed capacitance provides a buffering effect to prevent damage to the light source 14. As described above, this unique complementary pad structure significantly enhances the reliability of the light-emitting diode 1 in order to extend the service life of the light-emitting diode 1.

Additionally, this complementary pad structure improves the reliability of the light-emitting diode 1 by increasing the distributed capacitance of the light source 14, without the need for Zener diodes, isolated power supplies, or additional resistors, capacitors, or other circuit components. Therefore, the cost of lighting devices using this light-emitting diode 1 can be significantly reduced while still achieving high luminous efficiency. Consequently, the light-emitting diode 1 can be more comprehensive in application and meet actual requirements.

Furthermore, since the positive pad 12 includes the interconnected first main body 121 and first extension portion 122, and the negative pad 13 includes the second main body 131 and several second extension portions 132, the complementary pad structure significantly increases the surface area of both the positive pad 12 and the negative pad 13. This also enhances the heat dissipation area of the light-emitting diode 1. Additionally, the channels between the positive pad 12 and the negative pad 13 can serve as heat dissipation channels, which can further improve the heat dissipation efficiency of the light-emitting diode 1. Thus, the reliability of the light-emitting diode 1 is further enhanced, and the service life thereof can be also further extended.

Moreover, when the light-emitting diode 1 is connected to a power source and an input voltage is applied, the distributed capacitance provides instantaneous high-voltage suppression, preventing damage to the light source 14 caused by transient high voltages. Therefore, the reliability of the light-emitting diode 1 is further improved, which can align with future development trends.

The embodiment just exemplifies the present invention and is not intended to limit the scope of the present invention; any equivalent modification and variation according to the spirit of the present invention is to be also included within the scope of the following claims and their equivalents.

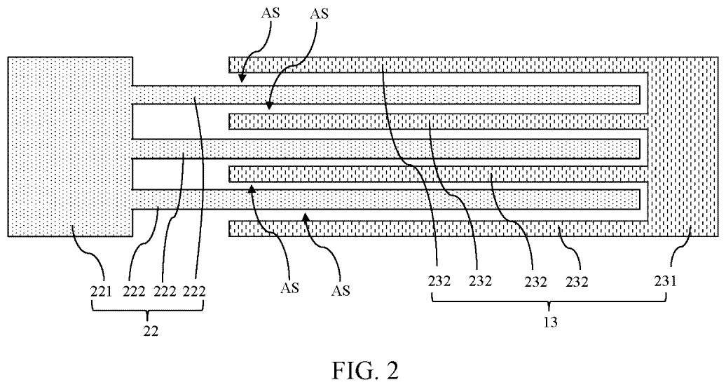

Please refer to FIG. 2, which is a cross-sectional view of a light-emitting diode with high reverse voltage tolerance in accordance with a second embodiment of the present invention. FIG. 2 only illustrates the positive pad 22 and the negative pad 23 of the light-emitting diode, while other components are the same as those in the previous embodiment and are not shown in FIG. 2.

The difference between this embodiment and the previous embodiment is that the positive pad 22 includes a first main body 221 and a plurality of first extension portions 222 connected to each other. The negative pad 23 includes a second main body 231 and a plurality of second extension portions 232 connected to the second main body 231. The number of second extension portions 232 is greater than the number of first extension portions 222. The second extension portions 232 extend toward the positive pad 22, which forms a plurality of accommodating spaces AS between the second extension portions 232. The first extension portions 222 correspond to the accommodating spaces AS respectively. Each first extension portion 222 extends toward the corresponding accommodating space AS. Thus, each first extension portion 222 is disposed between two adjacent second extension portions 232, and there is a gap between the first extension portion 222 and either of the second extension portion 232 adjacent to each other. In this embodiment, a part of the first extension portion 222 is disposed in the accommodating space AS, while another part is exposed outside the accommodating space AS. In another embodiment, the first extension portion 222 may also be entirely disposed in the accommodating space AS.

Similarly, a capacitor (distributed capacitance) can be formed between each first extension portion 222 and any adjacent second extension portion 232, and this capacitor is connected in parallel with the parasitic capacitance of the light source itself. As a result, the above structure is equal to light source connected in parallel with multiple capacitors, which increases the overall distributed capacitance of the light source 14. When a reverse voltage is applied to the light source 14, the distributed capacitance provides a buffering effect to prevent damage to the light source 14. As described above, this unique complementary pad structure significantly enhances the reliability of the light-emitting diode 1 in order to extend the service life of the light-emitting diode 1.

Additionally, this complementary pad structure further increases the surface area of both the positive pad 22 and the negative pad 23, enhancing the heat dissipation area of the light-emitting diode 1. Moreover, the channels between the positive pad 22 and the negative pad 23 can serve as heat dissipation channels, significantly improving the heat dissipation efficiency of the light-emitting diode 1. Therefore, the reliability of the light-emitting diode 1 is further enhanced and the service life of the light-emitting diode 1 can be further extended.

The embodiment just exemplifies the present invention and is not intended to limit the scope of the present invention; any equivalent modification and variation according to the spirit of the present invention is to be also included within the scope of the following claims and their equivalents.

It is worthy to point out that that most currently available lighting devices use metal housings to improve heat dissipation, and these metal housings are connected to a grounding point to comply with safety regulations. However, a parasitic capacitance is formed between the copper foil of the light source board and the metal housing. When the switch is turned on, an AC voltage is applied to the light sources on the light source board (which are connected to the copper foil). Since the parasitic capacitance conducts when an AC voltage is applied, the light sources on the light source board are subjected to a certain reverse voltage. If this reverse voltage is applied to the light sources for a long time, it to the light sources may be damaged due to this reverse voltage. To solve the above problems, several solutions have been proposed. One commonly used solution is to add a Zener diode to the circuit of the lighting device. However, this solution increases costs and reduces luminous efficiency. Another commonly used solution is to add an isolated power supply to the circuit of the lighting device. However, this solution also increases costs and reduces power efficiency. Yet another commonly used solution is to add a resistor (or capacitor) to the circuit of the lighting device and connect the resistor in parallel with the light sources. However, this solution also increases costs and reduces luminous efficiency. By contrast, according to one embodiment of the present invention, the light-emitting diode includes a holder, a positive pad, a negative pad and a light source. The positive pad is disposed in the holder, and includes a first main body and a first extension portion connected to each other. The negative pad is disposed in the holder, and includes a second main body and two second extension portions connected to the second main body. The light source is disposed in the holder and electrically connected to the positive pad and the negative pad. The second extension portions extend toward the positive pad to form an accommodating space between the second extension portions, and the first extension portion extends toward the accommodating space. As a result, a capacitor can be formed between the first extension portion and any adjacent second extension portion, which is equal to connecting the light source in parallel with multiple capacitors to increase the overall distributed capacitance of the light source. Thus, when a reverse voltage is applied to the light source, the distributed capacitance provides a buffering effect to prevent damage to the light source. As described above, this unique complementary pad structure significantly enhances the reliability of the light-emitting diode so as to extend the lifespan of the light-emitting diode.

According to one embodiment of the present invention, the light-emitting diode features the complementary pad structure design that improves reliability by increasing the distributed capacitance of the light source, without the need for Zener diodes or other circuit components. As a result, the cost of lighting devices using this light-emitting diode can be significantly reduced while still achieving high luminous efficiency. Therefore, the light-emitting diode can be more comprehensive in use and meet actual requirements.

According to one embodiment of the present invention, the light-emitting diode features the complementary pad structure design that improves reliability by increasing the distributed capacitance of the light source, without the need for isolated power supplies or other circuit components. As a result, the cost of lighting devices using this light-emitting diode can be significantly reduced while still achieving high power efficiency. Accordingly, the light-emitting diode can be more comprehensive in use and meet actual requirements.

According to one embodiment of the present invention, the light-emitting diode features the complementary pad structure design that improves reliability by increasing the distributed capacitance of the light source, without the need for additional resistors, capacitors, or other circuit components. As a result, the cost of lighting devices using this light-emitting diode can be significantly reduced while still achieving high luminous efficiency. Thus, the light-emitting diode can be more comprehensive in use and meet actual requirements.

Furthermore, according to one embodiment of the present invention, structure design of the the complementary pad light-emitting diode significantly increases the surface area of both the positive pad and the negative pad, thereby enhancing the heat dissipation area of the light-emitting diode. Additionally, the channels between the positive pad and the negative pad can serve as heat dissipation channels, significantly improving the heat dissipation efficiency of the light-emitting diode. Therefore, the reliability of the light-emitting diode is further enhanced, which can also extend the service life of the light-emitting diode.

Moreover, according to one embodiment of the present invention, the complementary pad structure design of the light-emitting diode significantly increases the distributed capacitance of each light source. Therefore, when the light-emitting diode is connected to a power source and an input voltage is applied, the distributed capacitance provides instantaneous high-voltage suppression, preventing damage to the light source caused by transient high voltages. In this way, the reliability of the light-emitting diode is further improved so as to conform to future development trends.

Additionally, according to one embodiment of the present invention, the complementary pad structure design of the light-emitting diode not only improves the luminous efficiency of the lighting device but also enhances the power efficiency thereof. Therefore, the overall performance of the lighting device can be effectively improved to meet the needs of different users.

Furthermore, according to one embodiment of the present invention, the design of the light-emitting diode is simple and achieves the desired effects while reducing costs. Therefore, the light-emitting diode offers high practicality, so the light-emitting diode can be more flexible in application and meet different application requirements. As described above, the light-emitting diode with high reverse voltage tolerance according to the embodiments of the present invention can achieve great technical effects.

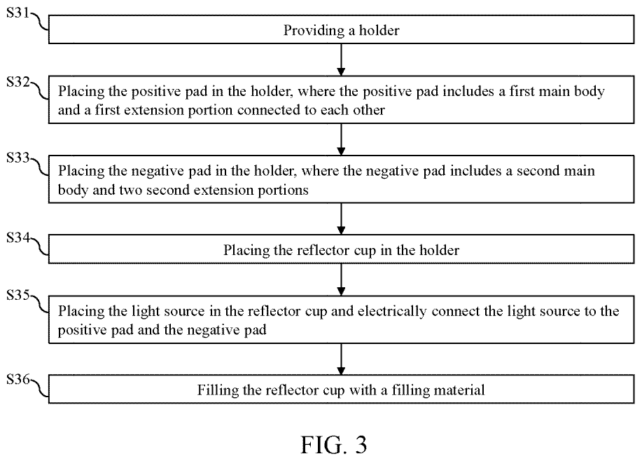

Please refer to FIG. 3, which is a flowchart of a manufacturing method of a light-emitting diode with high reverse voltage tolerance in accordance with a third embodiment of the present invention. As shown in FIG. 3, the manufacturing method of the light-emitting diode in this embodiment includes the following steps:

Step S31: providing a holder.

Step S32: placing the positive pad in the holder, where the positive pad includes a first main body and a first extension portion connected to each other.

Step S33: placing the negative pad in the holder, where the negative pad includes a second main body and two second extension portions. The second extension portions are connected to the second main body and extend toward the positive pad, which forms an accommodating space between the second extension portions. The first extension portion extends toward the accommodating space. A part of each first extension portion is disposed in the corresponding accommodating space. Each first extension portion is disposed between two adjacent second extension portions, and there is a gap between the first extension portion and either of the adjacent second extension portions.

Step S34: placing the reflector cup in the holder. The reflector cup may be made of metal, plastic, or other similar materials.

Step S35: placing the light source in the reflector cup and electrically connect the light source to the positive pad and the negative pad. The light source may be an LED die.

Step S36: filling the reflector cup with a filling material. The filling material may be a mixture of phosphor and adhesive.

As mentioned earlier, the first extension portion extends toward the accommodating space. Therefore, a capacitor can be formed between the first extension portion and any adjacent second extension portion, effectively connecting the light source in parallel with multiple capacitors to increase the overall distributed capacitance of the light source. Thus, when a reverse voltage is applied to the light source, the distributed capacitance provides a buffering effect to prevent damage to the light source. As described above, this unique complementary pad structure significantly enhances the reliability of the light-emitting diode in order to extend the service life of the light-emitting diode.

The embodiment just exemplifies the present invention and is not intended to limit the scope of the present invention; any equivalent modification and variation according to the spirit of the present invention is to be also included within the scope of the following claims and their equivalents.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

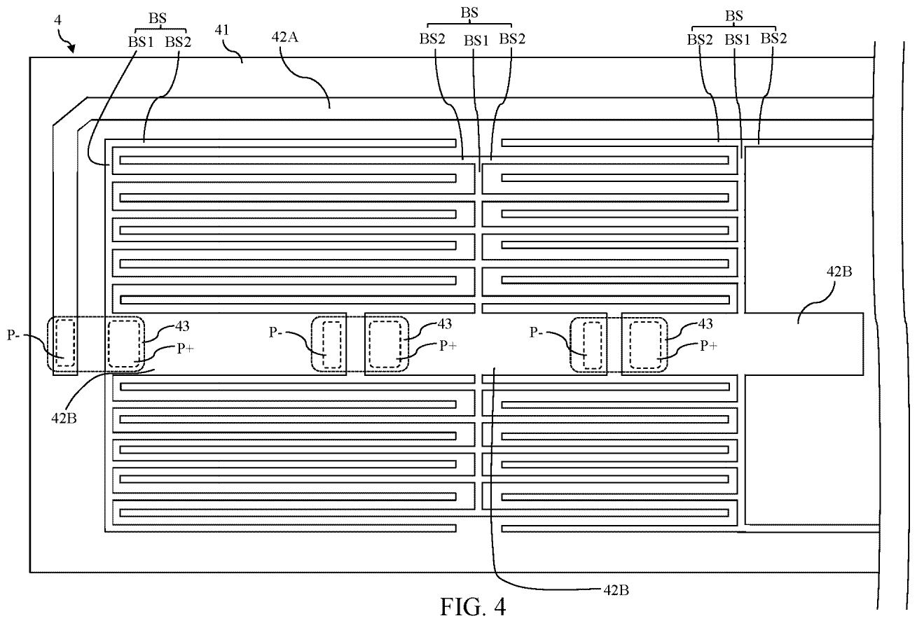

Please refer to FIG. 4, which is a top view of a structure of a light source board with a branch layout structure in accordance with a fourth embodiment of the present invention. As shown in FIG. 4, the light source board 4 includes a circuit board 41, a first copper foil 42A, a plurality of second copper foils 42B, a plurality of light-emitting diodes 43, a plurality of positive pads P+, and a plurality of negative pads P−. FIG. 4 only illustrates several light-emitting diodes 43 and several second copper foils 42B, and the number of these components can be adjusted according to actual requirements. The light-emitting diodes 43 may adopt the structure of the first or second embodiment. In another embodiment, the light-emitting diodes 43 may also be the currently available light-emitting diodes.

The first copper foil 42A is disposed on the circuit board 41. In one embodiment, the circuit board 41 may be a rigid circuit board or a flexible circuit board.

The second copper foils 42B are disposed on the circuit board 41. Each second copper foil 42B has two branch structures BS, which are respectively disposed on both sides of the second copper foil 42B and arranged opposite to each other. Each branch structure BS of each second copper foil 42B is interleaved with one branch structure BS of the second copper foil 42B adjacent thereto. The first copper foil 42A and the second copper foils 42B are electrically connected to a power source (not shown in FIG. 4). In this embodiment, the branch structure BS of each second copper foil 42B is tree-shaped. In another embodiment, the branch structure BS of each second copper foil 42B may also have other similar shapes.

The positive pads P+ and the negative pads P− are disposed on the circuit board 41.

The light-emitting diodes 43 are electrically connected to the first copper foil 42A and the second copper foils 42B. Specifically, the first copper foil 42A is provided with one positive pad P+; one end of each second copper foil 42B is provided with a negative pad P−, and the other end is provided with a positive pad P+. The first one of the light-emitting diodes 43 is disposed between the first copper foil 42A and the second copper foil 42B adjacent to the first copper foil 42A, and is soldered to the positive pad P+ and the negative pad P−. Each of the other light-emitting diodes 43 is disposed between two adjacent second copper foils 42B and is also soldered to the positive pad P+ of one second copper foil 42B and the negative pad P-of another second copper foil 42B. In this way, the light-emitting diodes 43 are electrically connected to the circuit board 41, the first copper foil 42A, and the second copper foils 42B.

In this embodiment, each branch structure BS of each second copper foil 42B includes a main extension portion BS1 and branch portions BS2 (the main extension portion BS1 and the branch portions BS2 are also made of copper foil). The main extension portion BS1 is connected to the second copper foil 42B, and the branch portions BS2 are connected to the main extension portion BS1. The branch portions BS2 may be disposed on one side or both sides of the main extension portion BS1. The extension direction of the main extension portion BS1 is perpendicular to the extension direction of the branch portions BS2. As mentioned earlier, each branch structure BS of each second copper foil 42B is interleaved with one branch structure BS of the second copper foil 42B adjacent thereto. Thus, each branch portion BS2 of each branch structure BS of each second copper foil 42B is adjacent to at least one branch portion BS2 of the branch structure BS of the second copper foil 42B adjacent thereto or is disposed between two branch portions BS2 of the branch structure BS of the second copper foil 42B adjacent thereto. In another embodiment, the angle between the extension direction of the main extension portion BS1 and the extension direction of the branch portions BS2 may be greater than 90 degrees. In yet another embodiment, the angle between the extension direction of the main extension portion BS1 and the extension direction of the branch portions BS2 may be less than 90 degrees.

The branch layout structure described above can increase the plate area of the positive pad P+ and the negative pad P-of each light-emitting diode 43. Additionally, two adjacent branch portions BS2 can form a capacitor. The capacitors formed by the branch portions BS2 are connected in parallel with the inherent distributed capacitance of the positive pad P+ and the negative pad P−. This technical effect is equivalent to increasing the capacitance value of the inherent distributed capacitance of the positive pad P+ and the negative pad P−. The larger the capacitance value, the smaller the capacitive reactance. Therefore, when a reverse voltage is applied to each light-emitting diode 43, most of the reverse voltage is distributed across the distributed capacitance, reducing the voltage borne by the light-emitting diode 43. As described above, when a reverse voltage is applied to each light-emitting diode 43, the distributed capacitance provides a buffering effect to prevent damage to the light-emitting diode 43. Thus, the unique branch layout structure significantly enhances the reliability of the light source board 4 so as to extend the service life of the light source board 4.

In this embodiment, the branch layout structure can improve the reliability of the light source board 4 by increasing the distributed capacitance of each light-emitting diode 43, without the need for Zener diodes, resistors, capacitors, or other circuit components. As a result, the cost of the light source board 4 can be significantly reduced while still achieving high luminous efficiency. Therefore, the light source board 4 can be more comprehensive in use and meet actual requirements.

Furthermore, in this embodiment, the branch layout structure can improve the reliability of the light source board 4 by increasing the distributed capacitance of each light-emitting diode 43, without the need for isolated power supplies or other circuit components. As a result, the cost of the light source board 4 can be significantly reduced while still achieving high power efficiency. Therefore, the light source board 4 can be more comprehensive in use and meet actual requirements.

In addition, in this embodiment, the branch layout structure can significantly increase the distributed capacitance of each light-emitting diode 43. Therefore, when the light source board 4 is connected to a power source and an input voltage is applied, the distributed capacitance provides instantaneous high-voltage suppression, preventing damage to the light-emitting diodes 43 caused by transient high voltages. Thus, the reliability of the light source board 4 is further improved with a view to aligning with future development trends.

The embodiment just exemplifies the present invention and is not intended to limit the scope of the present invention; any equivalent modification and variation according to the spirit of the present invention is to be also included within the scope of the following claims and their equivalents.

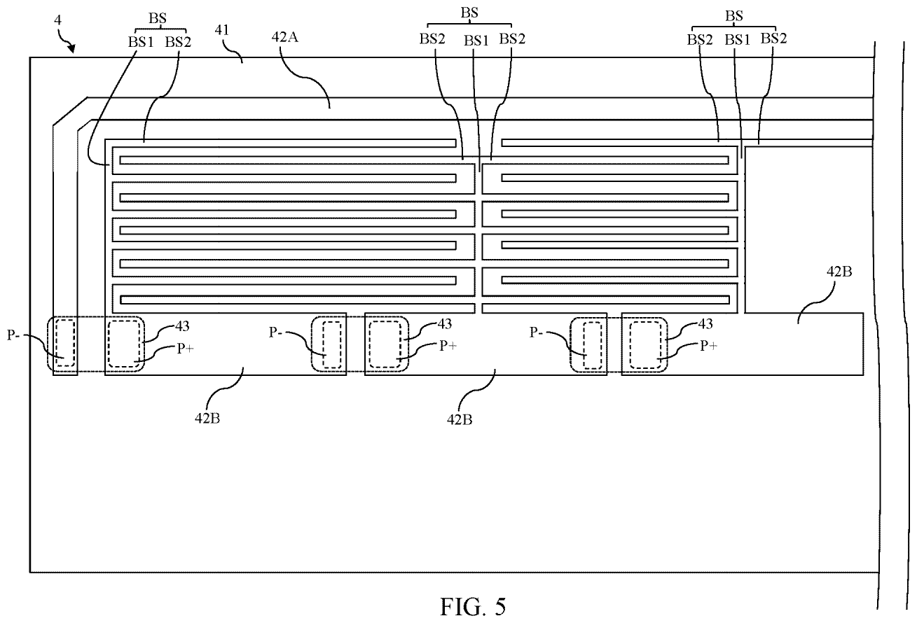

Please refer to FIG. 5, which is a top view of a structure of a light source board with a branch layout structure in accordance with a fifth embodiment of the present invention. As shown in FIG. 5, the light source board 4 includes a circuit board 41, a first copper foil 42A, a plurality of second copper foils 42B, a plurality of light-emitting diodes 43, a plurality of positive pads P+, and a plurality of negative pads P−. FIG. 5 only illustrates several light-emitting diodes 43 and several second copper foils 42B, and the number of these components can be adjusted according to actual requirements.

The first copper foil 42A is disposed on the circuit board 41. In one embodiment, the circuit board 41 may be a rigid circuit board or a flexible circuit board.

The second copper foils 42B are disposed on the circuit board 41.

The positive pads P+ and the negative pads P− are disposed on the circuit board 41.

The light-emitting diodes 43 are electrically connected to the first copper foil 42A and the e second copper foils 42B. Specifically, the first copper foil 42A is provided with one positive pad P+; one end of each second copper foil 42B is provided with a negative pad P−, and the other end is provided with a positive pad P+. The first one of the light-emitting diodes 43 is disposed between the first copper foil 42A and the second copper foil 42B adjacent to the first copper foil 42A, and is soldered to the positive pad P+ and the negative pad P−. Each of the other light-emitting diodes 43 is located between two adjacent second copper foils 42B and is also soldered to the positive pad P+ of one second copper foil 42B and the negative pad P-of another second copper foil 42B. In this way, the light-emitting diodes 43 are electrically connected to the circuit board 41, the first copper foil 42A, and the second copper foils 42B.

The components described above are similar to those in the previous embodiment, so the components will not be repeated here. The difference between this embodiment and the previous embodiment is that each second copper foil 42B has only one branch structure BS, which is disposed on one side of the second copper foil 42B.

Similarly, the branch structure BS of each second copper foil 42B is interleaved with the branch structure BS of an adjacent second copper foil 42B. The first copper foil 42A and the second copper foils 42B are electrically connected to a power source (not shown in FIG. 5). The branch structure BS of each second copper foil 42B is tree-shaped. Each branch structure BS includes a main extension portion BS1 and a plurality of branch portions BS2 (the main extension portion BS1 and the branch portions BS2 are also made of copper foil). The main extension portion BS1 is connected to the second copper foil 42B, and the branch portions BS2 are connected to the main extension portion BS1. The branch portions BS2 may be disposed on one side or both sides of the main extension portion BS1. The extension direction of the main extension portion BS1 is perpendicular to the extension direction of the branch portions BS2.

The branch layout structure described above can increase the plate area of the positive pad P+ and the negative pad P-of each light-emitting diode 43. Additionally, two adjacent branch portions BS2 can form a capacitor. The capacitors formed by the branch portions BS2 are connected in parallel with the inherent distributed capacitance of the positive pad P+ and the negative pad P−. This technical effect is equivalent to increasing the capacitance value of the inherent distributed capacitance of the positive pad P+ and the negative pad P−. The larger the capacitance value, the smaller the capacitive reactance. Therefore, when a reverse voltage is applied to each light-emitting diode 43, most of the reverse voltage is distributed across the distributed capacitance, reducing the voltage borne by the light-emitting diode 43. As described above, when a reverse voltage is applied to each light-emitting diode 43, the distributed capacitance provides a buffering effect to prevent damage to the light-emitting diode 43. Thus, the unique branch layout structure significantly enhances the reliability of the light source board 4 in order to extend the service life of the light source board 4.

Similarly, in this embodiment, the branch layout structure can improve the reliability of the light source board 4 by increasing the distributed capacitance of each light-emitting diode 43, without the need for Zener diodes, resistors, capacitors, or other circuit components. As a result, the cost of the light source board can be significantly reduced while still achieving high luminous efficiency. Therefore, the light source board can be more comprehensive in use and meet actual requirements.

Furthermore, in this embodiment, the branch layout structure can improve the reliability of the light source board 4 by increasing the distributed capacitance of each light-emitting diode 43, without the need for isolated power supplies or other circuit components. As a result, the cost of the light source board 4 can be significantly reduced while still achieving high power efficiency. Therefore, the light source board 4 can be more comprehensive in use and meet actual requirements.

Additionally, in this embodiment, the branch layout structure can significantly increase the distributed capacitance of each light-emitting diode 43. Therefore, when the light source board 4 is connected to a power source and an input voltage is applied, the distributed capacitance provides instantaneous high-voltage suppression, preventing damage to the light-emitting diodes 43 caused by transient high voltages. Thus, the reliability of the light source board 4 is further improved in order to align with future development trends.

The embodiment just exemplifies the present invention and is not intended to limit the scope of the present invention; any equivalent modification and variation according to the spirit of the present invention is to be also included within the scope of the following claims and their equivalents.

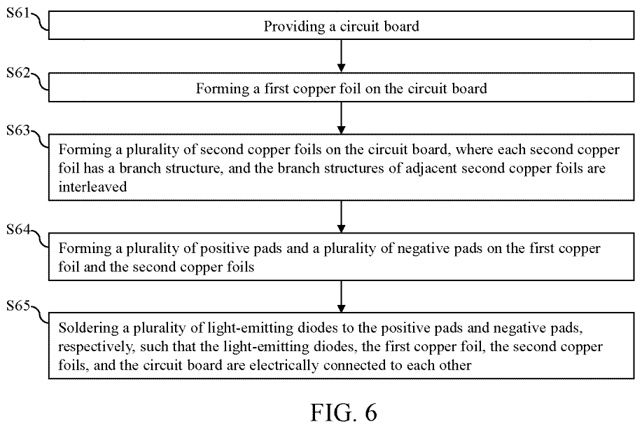

Please refer to FIG. 6, which is a flowchart of a manufacturing method of a light source board in accordance with a sixth embodiment of the present invention. As shown in FIG. 6, the manufacturing method of this embodiment includes the following steps:

Step S61: providing a circuit board.

Step S62: forming a first copper foil on the circuit board.

Step S63: forming a plurality of second copper foils on the circuit board, where each second copper foil has a branch structure, and the branch structures of adjacent second copper foils are interleaved. The branch structure of each second copper foil is tree-shaped. Additionally, each branch structure includes a main extension portion and a plurality of branch portions. The main extension portion is connected to the second copper foil, and the branch portions are connected to the main extension portion.

Step S64: forming a plurality of positive pads and a plurality of negative pads on the first copper foil and the second copper foils.

Step S65: soldering a plurality of light-emitting diodes to the positive pads and negative pads, respectively, such that the light-emitting diodes, the first copper foil, the second copper foils, and the circuit board are electrically connected to each other.

The embodiment just exemplifies the present invention and is not intended to limit the scope of the present invention; any equivalent modification and variation according to the spirit of the present invention is to be also included within the scope of the following claims and their equivalents.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

As described above, according to one embodiment of the present invention, the light source board includes a circuit board, a first copper foil, a plurality of second copper foil and a plurality of light-emitting diodes. The first copper foil is disposed of on the circuit board. The second copper foils are disposed on the circuit board, and each of the second copper foils has a branch structure. The light-emitting diodes are disposed of on the circuit board, and electrically connected to the first copper foil and the second copper foils. The branch structures of each of the second copper foils are interleaved with the branch structure of the second copper foil adjacent thereto. In addition, each branch portion of each branch structure of each second copper foil is adjacent to at least one branch portion of the branch structure of the second copper foil 42B adjacent thereto. Therefore, two adjacent branch portions can form a capacitor, which can effectively connect each light source in parallel with multiple capacitors to increase the distributed capacitance of each light source. Thus, when a reverse voltage is applied to each light source, the distributed capacitance provides a buffering effect to prevent damage to the light source. As described above, this unique branch layout structure significantly enhances the reliability of the light source board so as to extend the service life of the light source board.

According to the embodiments of the present invention, the light source board features a branch layout structure that improves reliability by increasing the distributed capacitance of each light source, without the need for Zener diodes or other circuit components. As a result, the cost of the light source board can be significantly reduced while still achieving high luminous efficiency. Therefore, the light source board can be more comprehensive in use and meet actual requirements.

According to the embodiments of the present invention, the light source board features a branch layout structure that improves reliability by increasing the distributed capacitance of each light source, without the need for isolated power supplies or other circuit components. As a result, the cost of the light source board can be significantly reduced while still achieving high power efficiency. Therefore, the light source board can be more comprehensive in use and meet actual requirements.

Furthermore, according to the embodiments of the present invention, the light source board features a branch layout structure that improves reliability by increasing the distributed capacitance of each light source, without the need for additional resistors, capacitors, or other circuit components. As a result, the cost of the light source board can be significantly reduced while still achieving high luminous efficiency. Therefore, the light source board can be more comprehensive in use and meet actual requirements.

Additionally, according to the embodiments of the present invention, the light source board features a branch layout structure that significantly increases the distributed capacitance of each light source. Therefore, when the light source board is connected to a power source and an input voltage is applied, the distributed capacitance provides instantaneous high-voltage suppression, preventing damage to the light sources caused by transient high voltages. Thus, the reliability of the light source board is further improved with a view to aligning with future development trends.

Moreover, according to the embodiments of the present invention, the branch layout structure of the light source board not only improves the luminous efficiency of the lighting device but also enhances the power efficiency thereof. Therefore, the overall performance of the lighting device can be effectively improved to meet the needs of different users.

Furthermore, according to the embodiments of the present invention, the design of the light source board is simple and achieves the desired effects while reducing costs. Therefore, the light source board offers high practicality, making it more flexible for various applications and better suited to meet different application requirements. As described above, the light source board with a branch layout structure according to the embodiments of the present invention can achieve great technical effects.

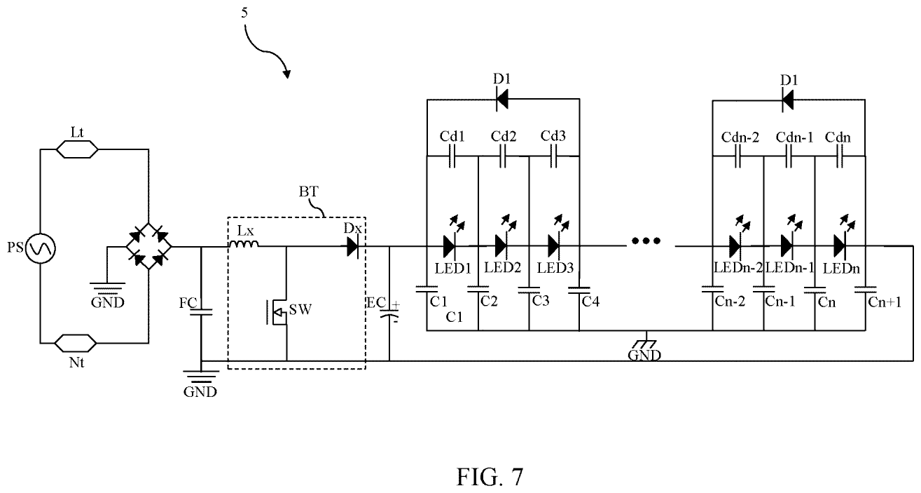

Please refer to FIG. 7, which is a circuit diagram of a lighting device with a reverse voltage clamp release mechanism in accordance with a seventh embodiment of the present invention. As shown in FIG. 7, the lighting device 5 includes a power input terminal, a rectifier RT, a filter capacitor FC, a transformer CT, an energy storage capacitor EC, a plurality of current-limiting diodes D1, and a plurality of light-emitting diodes LED1˜LEDn. The lighting device 5 also includes a fuse and an electromagnetic compatibility (EMC) filter module, but these components are well-known to those skilled in the art and are not shown in FIG. 7. The LEDS LED1˜LEDn may adopt the structure of the first or second embodiment. In another embodiment, the LEDS LED1˜LEDn may also be currently available light-emitting diodes.

The power input terminal includes a live wire input terminal Lt and a neutral wire input terminal Nt. The power input terminal is connected to an external power source PS and the rectifier RT. In one embodiment, the external power source PS is a mains power supply. In another embodiment, the external power source PS is a generator or another AC power source.

The rectifier RT is connected to the filter capacitor FC and the grounding point GND. In one embodiment, the rectifier RT is a full-wave rectifier. In another embodiment, the rectifier RT is a half-wave rectifier.

The filter capacitor FC is connected to the transformer CT, and the transformer CT is connected to the grounding point GND and the energy storage capacitor EC. In this embodiment, the transformer CT is a boost converter, which includes an inductor Lx, a switch SW, and a diode Dx. The circuit structure of the transformer CT is well-known to those skilled in the art and will not be described in detail here. In another embodiment, the transformer CT may be a buck converter or a buck-boost converter.

The energy storage capacitor EC is connected to the light-emitting diodes LED1˜LEDn.

The light-emitting diodes LED1˜LEDn can be divided into multiple groups. For example, in this embodiment, the light-emitting diodes LED1˜LED3 form one group. The light-emitting diodes LED4˜LED6 form another group, and so on, with the light-emitting diodes LEDn−2˜LEDn forming the last group. The light-emitting diodes in each group are connected in series to form a series circuit, and each series circuit is connected in parallel with a current-limiting diode D1. For example, the light-emitting diodes LED1˜LED3 form a series circuit, which is connected in parallel with a current-limiting diode D1. Similarly, the light-emitting diodes LEDn−2˜LEDn form a series circuit, which is connected in parallel with a current-limiting diode D1.

Each light-emitting diode LED1˜LEDn has a parasitic capacitance and a junction capacitance (the parasitic capacitance and junction capacitance are formed inside each light-emitting diode; the circuit in FIG. 7 is an equivalent circuit including these parasitic and junction capacitances). For example, the light-emitting diode LED1 has a parasitic capacitance C1 and a junction capacitance Cd1, with the junction capacitance Cd1 connected in parallel with the light-emitting diode LED1. The light-emitting diode LED2 has a parasitic capacitance C2 and a junction capacitance Cd2, with the junction capacitance Cd2 connected in parallel with the light-emitting diode LED2. The light-emitting diode LED3 has a parasitic capacitance C3 and a junction capacitance Cd3, with the junction capacitance Cd3 connected in parallel with the light-emitting diode LED3. The light-emitting diode LEDn−2 has a parasitic capacitance Cn−2 and a junction capacitance Cdn−2, with the junction capacitance Cdn−2 connected in parallel with the light-emitting diode LEDn−2. The light-emitting diode LEDn−1 has a parasitic capacitance Cn−1 and a junction capacitance Cdn−1, with the junction capacitance Cdn−1 connected in parallel with the light-emitting diode LEDn−1. The light-emitting diode LEDn has a parasitic capacitance Cn and a junction capacitance Cdn, with the junction capacitance Cdn connected in parallel with the light-emitting diode LEDn. The parasitic capacitance Cn+1 is the parasitic capacitance between the metal housing of the lighting device 5 and the light source board (on which the light-emitting diodes LED1˜LEDn are mounted).

When the user turns off the lighting device 5 by switching off either the live wire input terminal Lt or the neutral wire input terminal Nt, an AC voltage difference is generated between the light-emitting diodes LED1˜LEDn and the metal housing of the lighting device 5. As a result, the parasitic capacitances C1˜Cn of the light-emitting diodes LED1˜LEDn are continuously charged and discharged. This process generates a reverse voltage, which is applied to the light-emitting diodes LED1˜LEDn (for example, the voltage at the cathode of the light-emitting diode LED1 becomes higher than the voltage at the anode thereof). Each current-limiting diode D1 forms a discharge path, and the discharge current generated by the parasitic capacitances C1˜Cn of the light-emitting diodes LED1˜LEDn can be released via these discharge paths. For example, the current-limiting diode D1 connected in parallel with the series circuit formed by the light-emitting diodes LED1˜LED3 forms a discharge path, and the discharge current generated by the parasitic capacitances C1˜C3 of the light-emitting diodes LED1˜LED3 can be released via this discharge path. Since the voltage drop across the current-limiting diode D1 when the current-limiting diode D1 is conducting is much smaller than the reverse voltage that the light-emitting diodes LED1˜LED3 can withstand, the impact of the reverse voltage on the cathodes of the light-emitting diodes LED1˜LED3 is reduced. Therefore, the current-limiting diode D1 achieves a reverse voltage clamp release mechanism, which can effectively reduce the reverse voltage. Additionally, the junction capacitance of the current-limiting diode D1 can stabilize the voltage difference across the series circuit formed by the light-emitting diodes LED1˜LED3 when the lighting device 5 is turned on, reducing the impact on the light-emitting diodes LED1˜LED3. Similarly, the current-limiting diode D1 connected in parallel with the series circuit formed by the light-emitting diodes LEDn−2˜LEDn forms a discharge path, and the discharge current generated by the parasitic capacitances Cn−2˜Cn of the light-emitting diodes LEDn−2˜LEDn can be released via this discharge path. The junction capacitances Cd1˜Cdn of the light-emitting diodes LED1˜LEDn can also contribute to reducing the reverse voltage to some extent.

As previously stated, each current-limiting diode D1 forms a discharge path, and the discharge current generated by the parasitic capacitances C1˜Cn of the light-emitting diodes LED1˜LEDn is released via the discharge paths, realizing the reverse voltage clamp release mechanism. Through this reverse voltage clamp release mechanism, the light-emitting diodes LED1˜LEDn are protected from damage due to reverse voltage, thereby improving the reliability of the lighting device 5.

In this embodiment, the current-limiting diodes D1 in the lighting device 5 also have junction capacitances. When the lighting device 5 is turned on, a transient high voltage may be applied to the light-emitting diodes LED1˜LEDn. At this time, the junction capacitances of the current-limiting diodes D1 can effectively provide a buffering effect. This mechanism prevents the light-emitting diodes LED1˜LEDn from being damaged by transient high voltages. Therefore, the reliability of the lighting device 5 is further improved so as to conform to actual requirements.

Additionally, in this embodiment, the circuit design and operation mechanism of the lighting device 5 effectively implement a unique reverse voltage clamp release mechanism, significantly enhancing the reliability of the lighting device 5. Moreover, since the reverse voltage clamp release mechanism is achieved via discharge paths, it does not reduce the luminous efficiency of the lighting device 5. Therefore, the lighting device 5 can be more comprehensive in application and more flexible in use.

Furthermore, in this embodiment, the lighting device 5 improves its reliability through the unique reverse voltage clamp release mechanism without the need for isolated power supplies or complex manufacturing processes. As a result, the circuit loss of the lighting device 5 is effectively reduced, and the energy efficiency thereof is significantly improved, which can align with future development trends.

Moreover, in this embodiment, the lighting device 5 can improve its reliability through the unique reverse voltage clamp release mechanism without compromising the heat dissipation performance thereof. Therefore, the lighting device 5 still achieves excellent heat dissipation, preventing malfunctions or reduced service life due to overheating.

The embodiment just exemplifies the present invention and is not intended to limit the scope of the present invention; any equivalent modification and variation according to the spirit of the present invention is to be also included within the scope of the following claims and their equivalents.

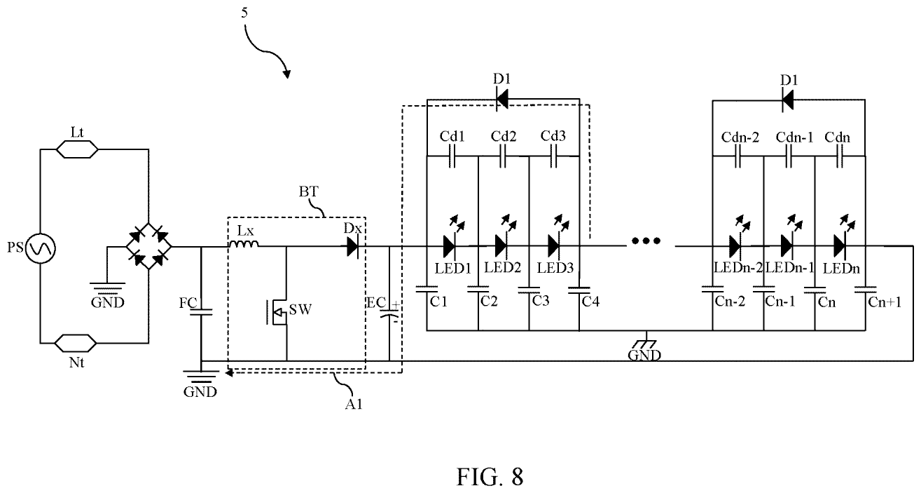

Please refer to FIG. 8, which is a schematic view of an operating state of the lighting device with the reverse voltage clamp release mechanism in accordance with the seventh embodiment of the present invention. As shown in FIG. 8, the current-limiting diode D1 connected in parallel with the series circuit formed by the light-emitting diodes LED1˜LED3 forms a discharge path, and the discharge current generated by the parasitic capacitances C1˜C3 of the light-emitting diodes LED1˜LED3 is released via this discharge path. The discharge current from the light-emitting diodes LED1˜LED3 flows through the current-limiting diode D1, the energy storage capacitor EC, and the transformer CT to the grounding point GND, as indicated by arrow Al in FIG. 8. Similarly, the discharge paths formed by other current-limiting diodes D1 operate in the same manner.

The embodiment just exemplifies the present invention and is not intended to limit the scope of the present invention; any equivalent modification and variation according to the spirit of the present invention is to be also included within the scope of the following claims and their equivalents.

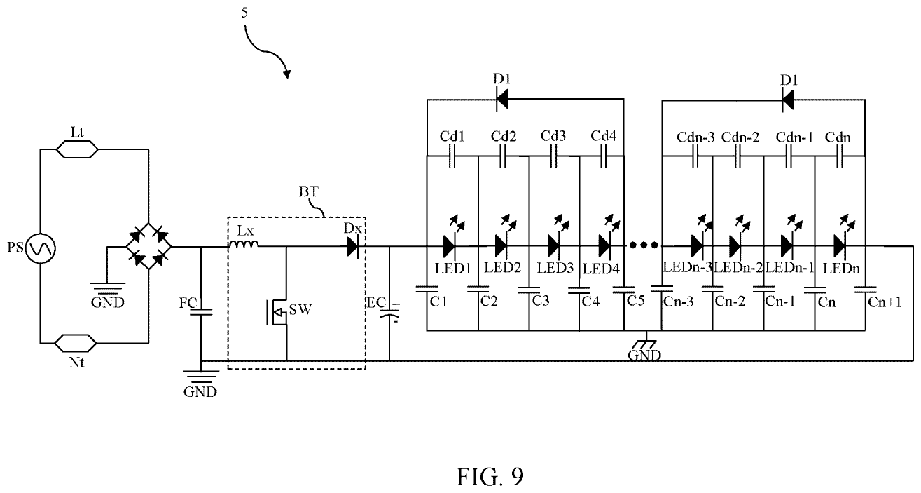

Please refer to FIG. 9, which is a circuit diagram of a lighting device with a reverse voltage clamp release mechanism in accordance with an eighth embodiment of the present invention. As shown in FIG. 9, the lighting device 5 includes a power input terminal, a rectifier RT, a filter capacitor FC, a transformer CT, an energy storage capacitor EC, a plurality of current-limiting diodes D1, and a plurality of light-emitting diodes LED1˜LEDn. The lighting device 5 also includes a fuse and an electromagnetic compatibility (EMC) filter module, but these components are well-known to those skilled in the art and are not shown in FIG. 8.

The power input terminal includes a live wire input terminal Lt and a neutral wire input terminal Nt. The power input terminal is connected to an external power source PS and the rectifier RT. The rectifier RT is connected to the filter capacitor FC and the grounding point GND. The filter capacitor FC is connected to the transformer CT, and the transformer CT is connected to the grounding point GND and the energy storage capacitor EC. The energy storage capacitor EC is connected to the light-emitting diodes LED1˜LEDn.

The light-emitting diodes LED1˜LEDn can be divided into multiple groups. The difference between this embodiment and the previous embodiment is that the light-emitting diodes LED1˜LED4, in this embodiment, form one group. The light-emitting diodes LED5˜LED8 form another group, and so on, with the light-emitting diodes LEDn−3˜LEDn forming the last group. The light-emitting diodes in each group are connected in series to form a series circuit, and each series circuit is connected in parallel with a current-limiting diode D1. For example, the light-emitting diodes LED1˜LED4 form a series circuit, which is connected in parallel with a current-limiting diode D1. Similarly, the light-emitting diodes LEDn−3˜LEDn form a series circuit, which is connected in parallel with a current-limiting diode D1.

As described above, the number of light-emitting diodes in each series circuit can be adjusted according to actual requirements to optimize the reverse voltage clamp release mechanism, enabling the lighting device 5 to achieve higher reliability.

The embodiment just exemplifies the present invention and is not intended to limit the scope of the present invention; any equivalent modification and variation according to the spirit of the present invention is to be also included within the scope of the following claims and their equivalents.

As described above, according to one embodiment of the present invention, the lighting device includes a current-limiting diode, a plurality of light-emitting diodes, a rectifier, and a power input terminal. The light-emitting diodes are connected in series to form a series circuit, and the series circuit is connected in parallel with the current-limiting diode. Each of the light-emitting diodes has a parasitic capacitor. The rectifier is connected to the light-emitting diodes, and the power input terminal is connected to an external power source and the rectifier. The current-limiting diode forms a discharge path, and the discharge current generated by the parasitic capacitor of each of the light-emitting diodes is released via the discharge path, which realizes a reverse voltage clamp release mechanism. Via this reverse voltage clamp release mechanism, the light-emitting diodes are protected from damage due to reverse voltage, thereby improving the reliability of the lighting device.

According to one embodiment of the present invention, the current-limiting diodes in the lighting device have junction capacitances. When the lighting device is turned on, a transient high voltage may be applied to the light-emitting diodes. At this time, the junction capacitances of the current-limiting diodes can effectively provide a buffering effect. This mechanism prevents the light-emitting diodes from being damaged by transient high voltages. Therefore, the reliability of the lighting device is further improved in order to meet actual requirements.

Furthermore, according to one embodiment of the present invention, the circuit design and operation mechanism of the lighting device effectively implement a unique reverse voltage clamp release mechanism, significantly enhancing the reliability of the lighting device. Additionally, since the reverse voltage clamp release mechanism is achieved via discharge paths, the luminous efficiency of the lighting device is not reduced. Therefore, the lighting device can be more comprehensive in application and more flexible in use.

Moreover, according to one embodiment of the present invention, the lighting device improves the reliability thereof via the unique reverse voltage clamp release mechanism without the need for isolated power supplies or complex manufacturing processes. As a result, the circuit loss of the lighting device is effectively reduced, and the energy efficiency thereof is significantly improved with a view to aligning with future development trends.

Additionally, according to one embodiment of the present invention, the lighting device can improve the reliability via the unique reverse voltage clamp release mechanism without compromising the heat dissipation performance thereof. Therefore, the lighting device still achieves excellent heat dissipation, preventing malfunctions or reduced service life due to overheating.

Furthermore, according to one embodiment of the present invention, the circuit design of the lighting device is simple and effectively implements a reverse voltage clamp release mechanism, enhancing the reliability of the lighting device. Therefore, the practicality of the lighting device is significantly improved, meeting the needs of various applications. As set forth above, the lighting device with the reverse voltage clamp release mechanism according to the embodiments of the present invention can achieve great technical effects.

It will be apparent to those skilled in the art that various modifications and variations can be made to the disclosed embodiments. It is intended that the specification and examples be considered as exemplary only, with a true scope of the present invention being indicated by the following claims and their equivalents.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A light-emitting diode with high reverse voltage tolerance, comprising:
a holder;
a positive pad disposed in the holder, and comprising a first main body and a first extension portion connected to each other;
a negative pad disposed in the holder, and comprising a second main body and two second extension portions connected to the second main body; and
a light source disposed in the holder and electrically connected to the positive pad and the negative pad;
wherein the second extension portions extend toward the positive pad to form an accommodating space between the second extension portions, and the first extension portion extends toward the accommodating space.

2. The light-emitting diode with high reverse voltage tolerance as claimed in claim 1, wherein a part of the first extension portion is disposed in the accommodating space.

3. The light-emitting diode with high reverse voltage tolerance as claimed in claim 1, wherein the first extension portion is disposed between the second extension portions, and there is a gap between the first extension portion and any one of the second extension portions.

4. The light-emitting diode with high reverse voltage tolerance as claimed in claim 1, wherein the cross-section of the negative pad is U-shaped.

5. The light-emitting diode with high reverse voltage tolerance as claimed in claim 1, further comprising a reflector cup disposed within the holder, wherein the light source is disposed in the reflector cup, and the reflector cup is filled with a filling material.

6. A light source board, comprising a circuit board and a plurality of light-emitting diodes, wherein the light-emitting diodes are disposed on the circuit board, and each of the light-emitting diodes is as claimed in claim 1.

7. The light source board as claim in claim 6, further comprising a first copper foil and a plurality of second copper foils, wherein the light-emitting diodes are electrically connected to the first copper foil and the plurality of second copper foils, the first copper foil is disposed on the circuit board, the second copper foils are disposed on the circuit board, and each of the second copper foils has a branch structure, wherein the branch structures of each of the second copper foils are interleaved with the branch structure of the second copper foil adjacent thereto.

8. A lighting device, comprising a plurality of light-emitting diodes, wherein the light-emitting diodes are connected in series to form a series circuit, and each of the light-emitting diodes is as claimed in claim 1.

9. The lighting device as claimed in claim 8, further comprising a current-limiting diode, a rectifier, and a power input terminal, wherein the series circuit is connected in parallel with the current-limiting diode, the rectifier is connected to the light-emitting diodes, the power input terminal is connected to an external power source and the rectifier, and each of the light-emitting diodes has a parasitic capacitor, wherein the current-limiting diode forms a discharge path, and a discharge current generated by the parasitic capacitor of each of the light-emitting diodes is released via the discharge path.

10. A light-emitting diode with high reverse voltage tolerance, comprising:
a holder;
a positive pad disposed in the holder, and comprising a first main body and a plurality of first extension portions connected to each other;
a negative pad disposed in the holder, and comprising a second main body and a plurality of second extension portions connected to the second main body; and
a light source disposed in the holder and electrically connected to the positive pad and the negative pad;
wherein the second extension portions extend toward the positive pad to form a plurality of accommodating spaces between the second extension portions corresponding to the first extension portions respectively, and each of the first extension portions extends toward the accommodating space corresponding thereto.

11. The light-emitting diode with high reverse voltage tolerance as claimed in claim 10, wherein a part of each of the first extension portions is disposed in the accommodating space corresponding thereto.

12. The light-emitting diode with high reverse voltage tolerance as claimed in claim 10, wherein each of the first extension portions is disposed between two the second extension portions adjacent with each other, and there is a gap between the first extension portion and any one of the second extension portions adjacent with each other.

13. The light-emitting diode with high reverse voltage tolerance as claimed in claim 10, wherein a number of the second extension portions is greater than a number of the first extension portions.

14. The light-emitting diode with high reverse voltage tolerance as claimed in claim 10, further comprising a reflector cup disposed in the holder, wherein the light source is disposed in the reflector cup, and the reflector cup is filled with a filling material.

15. A light source board, comprising a circuit board and a plurality of light-emitting diodes, wherein the light-emitting diodes are disposed on the circuit board, and each of the light-emitting diodes is as claimed in claim 10.

16. The light source board as claimed in claim 15, further comprising a first copper foil and a plurality of second copper foils, wherein the light-emitting diodes are electrically connected to the first copper foil and the plurality of second copper foils, the first copper foil is disposed on the circuit board, the second copper foils are disposed on the circuit board, and each of the second copper foils has a branch structure, wherein the branch structure of each of the second copper foils are interleaved with the branch structure of the second copper foil adjacent thereto.

17. A lighting device, comprising a plurality of light-emitting diodes, wherein the light-emitting diodes are connected in series to form a series circuit, and each of the light-emitting diodes is as claimed in claim 10.

18. The lighting device as claimed in claim 17, further comprising a current-limiting diode, a rectifier, and a power input terminal, wherein the series circuit is connected in parallel with the current-limiting diode, the rectifier is connected to the light-emitting diodes, the power input terminal is connected to an external power source and the rectifier, and each of the light-emitting diodes has a parasitic capacitor, wherein the current-limiting diode forms a discharge path, and a discharge current generated by the parasitic capacitor of each of the light-emitting diodes is released via the discharge path.
